(19) United States
(12) Patent Application Publication
(10) Pub. No.: US 2024/0274557 A1
(43) Pub. Date: Aug. 15, 2024

(54) SEMICONDUCTOR DEVICE AND POWER CONVERTING DEVICE

(71) Applicant: Mitsubishi Electric Corporation, Tokyo (JP)

(72) Inventors: Yo TANAKA, Chiyoda-ku, Tokyo (JP); Tetsu NEGISHI, Chiyoda-ku, Tokyo (JP); Seiji OKA, Chiyoda-ku, Tokyo (JP)

(73) Assignee: Mitsubishi Electric Corporation, Tokyo (JP)

(21) Appl. No.: 18/568,291

(22) PCT Filed: Jun. 14, 2021
(86) PCT No.: PCT/JP2021/022530

§ 371 Date: Dec. 8, 2023

(51) Int. Cl. H01L 23/00; H02M 7/5387

(52) U.S. Cl. CPC H01L 24/05; H01L 24/04; H01L 24/37; H01L 24/40; H01L 24/45; H01L 24/48; H01L 24/03; H01L 24/29; H01L 24/32; H01L 24/49; H01L 24/73; H01L 2224/03436; H01L 2224/04034; H01L 2224/04042; H01L 2224/05013; H01L 2224/05073; H01L 2224/05124; H01L 2224/05139; H01L 2224/05147; H01L 2224/05155; H01L 2224/05553; H01L 2224/05557; H01L 2224/05564; H01L 2224/05573; H01L 2224/05624; H01L 2224/05644; H01L 2224/05647; H01L 2224/05655; H01L 2224/0568; H01L 2224/29111; H01L 2224/29116; H01L 2224/29139; H01L 2224/29147; H01L 2224/2929; H01L 2224/29339; H01L 2224/29347; H01L 2224/32225; H01L 2224/37124; H01L 2224/37147; H01L 2224/40225; H01L 2224/40499; H01L 2224/45147; H01L 2224/48091; H01L 2224/48225; H01L 2224/49111; H01L 2224/49176; H01L 2224/73263; H01L 2224/73265; H01L 2924/01029; H01L 2924/01047; H01L 2924/0105; H01L 2924/01082; H01L 2924/0665; H02M 7/5387

(57) ABSTRACT

A surface electrode on the front surface of a semiconductor element and a metal foil provided on the surface electrode are partially joined, which makes it possible to reduce stress generated at the end of the metal foil, prevent a failure resulting from a crack in the front surface of the semiconductor element, and enhance reliability of the semiconductor device. Such a semiconductor device includes a semiconductor element having a front surface and a back surface, a surface electrode formed on the front surface of the semiconductor element, and a metal foil partially joined onto an upper surface of the surface electrode.

### TECHNICAL FIELD

The present disclosure relates to a semiconductor device including a metal foil partially bonded to a surface electrode, and a power converting device.

### BACKGROUND ART

In a semiconductor device using a power semiconductor element for electric power, a wire material mainly containing aluminum (Al) is wired on a surface electrode of the power semiconductor element to guarantee mechanical and electrical connection. In recent years, a structure using copper (Cu) having higher strength than Al as a wire material has been developed to extend the life of joint of the wire material, that is, to enhance the reliability of a semiconductor device.

In the case of such a semiconductor device, it is necessary to form, on the power semiconductor element, a surface electrode also mainly containing Cu and having high strength in order to join the wire material made of Cu to the surface electrode of the power semiconductor element without damage.

However, such a surface electrode requires the formation of a metal having high strength by a film forming method such as plating, which may complicate the production process.

Therefore, in the case of a conventional semiconductor device, a high-strength film including a metal sintered layer is formed on the entire surface of surface electrode of a power semiconductor element to make the production process simpler than that using a film forming method such as plating and to join a wire material mainly containing Cu to the power semiconductor element without damage (for example, PTL 1, PTL 2).

### CITATION LIST

### Patent Literature

PTL 1: Japanese Patent Laying-Open No. 2018-147967
PTL 2: WO 2016/071079

### SUMMARY OF INVENTION

### Technical Problem

However, in the case of semiconductor devices disclosed in PTL 1 and PTL 2, the metal sintered layer is formed on the entire surface of the power semiconductor element. Therefore, stress is generated at the joint between the metal sintered layer and the power semiconductor element during the use of the power semiconductor device, which may deteriorate the reliability of the semiconductor device due to the formation of a crack in the surface of the power semiconductor element.

In order to solve such a problem as described above, it is an object of the present disclosure to obtain a semiconductor device having enhanced reliability by providing a metal foil partially joined to the surface electrode of a semiconductor element.

### Solution to Problem

The present disclosure is directed to a semiconductor device including a semiconductor element having a front surface and a back surface, a surface electrode formed on the front surface of the semiconductor element, and a metal foil partially joined onto an upper surface of the surface electrode.

### Advantageous Effects of Invention

According to the present disclosure, the metal foil is partially joined to the surface electrode of the semiconductor element, which makes it possible to reduce stress generated at the end of the metal foil, prevent a failure caused by cracking in the surface of the semiconductor element, and enhance the reliability of the semiconductor device.

### BRIEF DESCRIPTION OF DRAWINGS

FIG. 1 is a schematic view showing the planar structure of a semiconductor device according to Embodiment 1.

FIG. 2 is a schematic view showing the sectional structure of the semiconductor device according to Embodiment 1.

FIG. 3 is a schematic view showing the planar structure of a metal foil of the semiconductor device according to Embodiment 1.

FIG. 4 is a schematic view showing the planar structure of a metal foil of another semiconductor device according to Embodiment 1.

FIG. 5 is a schematic view showing the planar structure of a metal foil of another semiconductor device according to Embodiment 1.

FIG. 6 is a schematic view showing the planar structure of a metal foil of another semiconductor device according to Embodiment 1.

FIG. 7 is a schematic view showing the planar structure of a metal foil of another semiconductor device according to Embodiment 1.

FIG. 8 is a schematic view showing the planar structure of a metal foil of another semiconductor device according to Embodiment 1.

FIG. 9 is a schematic view showing the planar structure of a metal foil of another semiconductor device according to Embodiment 1.

FIG. 10 is a schematic view showing the planar structure of a metal foil of another semiconductor device according to Embodiment 1.

FIG. 11 is a schematic view showing the sectional structure of outer periphery of a conventional semiconductor device.

FIG. 12 is a schematic view showing the sectional structure of outer periphery of the conventional semiconductor device.

FIG. 13 is a schematic view showing the sectional structure of outer periphery of the semiconductor device according to Embodiment 1.

FIG. 14 is a schematic view showing the sectional structure of outer periphery of the semiconductor device according to Embodiment 1.

FIG. 15 is a schematic view showing the planar structure of a semiconductor device according to Embodiment 2.

FIG. 16 is a schematic view showing the sectional structure of the semiconductor device according to Embodiment 2.

FIG. 17 is a block diagram showing the configuration of a power converting system to which a power converting device according to Embodiment 3 is applied.

### DESCRIPTION OF EMBODIMENTS

First, the entire configuration of a semiconductor device according to the present disclosure will be described with reference to the drawings. It should be noted that the drawings are schematic and do not necessarily reflect exact dimensions of components shown therein. Further, the same reference signs indicate the same or equivalent components, which is common throughout the specification.

### Embodiment 1

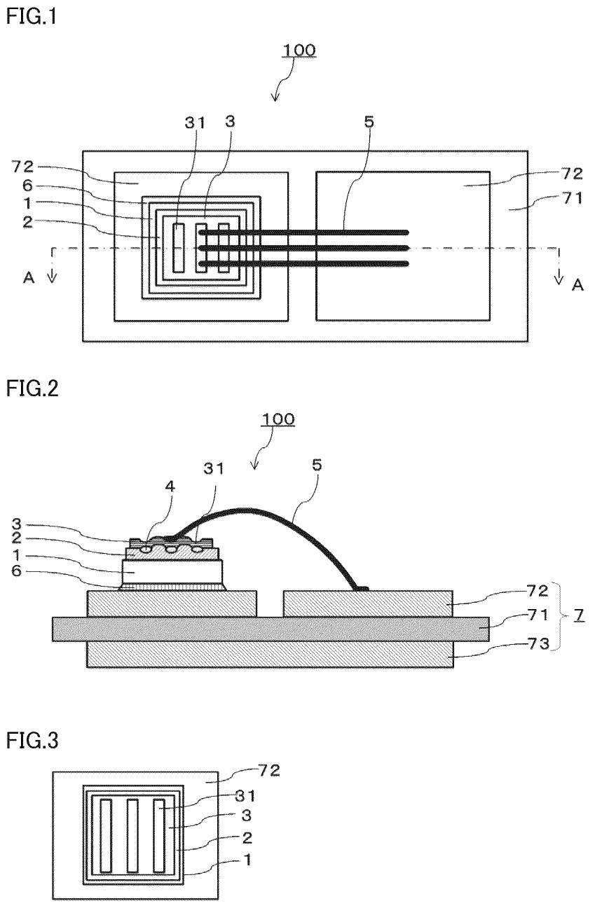

FIG. 1 is a schematic view showing the planar structure of a semiconductor device according to Embodiment 1. FIG. 2 is a schematic view showing the sectional structure of the semiconductor device according to Embodiment 1. FIG. 2 is a schematic sectional structural view taken along a dashed-dotted line AA shown in FIG. 1.

In the drawings, a semiconductor device 100 includes a power semiconductor element 1 as a semiconductor element, a surface electrode 2, a metal foil 3, a stir region 4, a wiring member 5, solder 6 as a joining material, and an insulating substrate 7.

In the drawings, the back surface of power semiconductor element 1 is joined to a metallic layer 72 on the upper surface side of insulating substrate 7 with solder 6. On the front surface of power semiconductor element 1, surface electrode 2 is formed. On the upper surface of surface electrode 2, metal foil 3 is formed. Surface electrode 2 and metal foil 3 are partially joined, and a joint region between surface electrode 2 and metal foil 3 corresponds to stir region 4. On the upper surface of metal foil 3, wires 5 as a wiring member are formed.

In the drawings, semiconductor device 100 is configured to have one power module having one power semiconductor element 1 and three wires 5. However, semiconductor device 100 may be configured to have a plurality of power modules each having one or more power semiconductor elements 1 and wires 5, the number of which is less than three or greater than or equal to three.

FIG. 1 is a schematic planar structural view when semiconductor device 100 is viewed from the upper surface side. In FIG. 1, the outermost full line corresponds to the outer edge of an insulating layer 71 of insulating substrate 7. On the inner side of the outer edge of insulating layer 71 of insulating substrate 7, metallic layer 72 on the upper surface side of insulating substrate 7 is disposed. In FIG. 1, two metallic layer 72 are disposed on the upper surface of insulating layer 71 of insulating substrate 7. On the inner side of the outer edge of left-hand metallic layer 72 on the upper surface side of insulating substrate 7, power semiconductor element 1 is disposed. On the inner side of the outer edge of front surface of power semiconductor element 1, surface electrode 2 is disposed. On the inner side of the outer edge of surface electrode 2, metal foil 3 is disposed. On the upper surface of metal foil 3, a dent 31 of metal foil 3 is disposed in a region corresponding to stir region 4 as a joint region between surface electrode 2 and the lower surface of metal foil 3. On the upper surface of metal foil 3, wires 5 are disposed. Wires 5 are disposed across a gap (space) between the opposed outer edges of left-hand metallic layer 72 and right-hand metallic layer 72 on the upper surface side of insulating substrate 7. Wires 5 are disposed on power semiconductor element 1 on the inner side of the outer edge of left-hand metallic layer 72 on the upper surface side of insulating substrate 7 and on the inner side of the outer edge of right-hand metallic layer 72.

FIG. 2 is a schematic sectional view of semiconductor device 100. In FIG. 2, the back surface of power semiconductor element 1 is joined to right-hand metallic layer 72 on the upper surface side of the insulating substrate 7 with solder 6. On the upper surface of surface electrode 2 on the front surface of power semiconductor element 1, metal foil 3 is disposed. The lower surface of metal foil 3 and the front surface of surface electrode 2 are partially joined via stir region 4. Metal foil 3 has an unlevel (wavy) sectional shape. Metal foil 3 is joined to the upper surface of surface electrode 2 of power semiconductor element 1 by pressing metal foil 3 against the upper surface of surface electrode 2 with a jig. At this time, dent 31 is formed in metal foil 3 as an indentation. A region between adjacent dents 31 is in contact with surface electrode 2 deformed and lifted in reflection of the shape of metal foil 3. In the outer peripheral region of metal foil 3, the lower surface of metal foil 3 is not joined to the upper surface of surface electrode 2 of power semiconductor element 1. Therefore, the outer peripheral region of metal foil 3 can change in shape. On the upper surface of metal foil 3, wires 5 are connected (joined).

Power semiconductor element 1 is a power semiconductor element for electric power. The material of power semiconductor element 1 may be, for example, silicon (Si), silicon carbide (SiC), or gallium nitride (GaN). Power semiconductor element 1 is a power device such as a metal oxide semiconductor field effect transistor (MOSFET), an insulated gate bipolar transistor (IGBT), a free wheel diode (FWD), a reverse conducting IGBT (RC-IGBT), or the like. However, the type of power semiconductor element 1 is not limited thereto. In FIG. 1 and FIG. 2, the number of power semiconductor elements 1 is one. However, the number of power semiconductor elements 1 is not limited thereto.

Power semiconductor element 1 has a structure in which surface electrode 2 is disposed on the front surface of power semiconductor element 1 and a back electrode (not shown) is disposed on the back surface of power semiconductor element 1. Power semiconductor element 1 is joined to the upper surface of left-hand metallic layer 72 on the upper surface side of insulating substrate 7 with solder 6 as a joint. Surface electrode 2 of power semiconductor element 1 is disposed on the opposite side of the center of power semiconductor element 1 from the back electrode not shown. Surface electrode 2 of power semiconductor element 1 is partially joined to metal foil 3 via stir region 4. The back electrode (not shown) of power semiconductor element 1 is joined to the upper surface of left-hand metallic layer 72 on the upper surface side of insulating substrate 7 with solder 6.

Surface electrode 2 of power semiconductor element 1 includes, for example, a control signal electrode, a main electrode, and the like, but the type of surface electrode 2 of power semiconductor element 1 is not limited thereto. Surface electrode 2 of power semiconductor element 1 may be one of a control signal electrode and a main electrode. The material of surface electrode 2 of power semiconductor element 1 may be aluminum (Al), copper (Cu), silver (Ag), nickel (Ni), gold (Au), or an alloy mainly containing any one of these from the viewpoint of electrical characteristics and mechanical characteristics.

Joining material 6 is disposed between the back electrode (not shown) of power semiconductor element 1 and left-hand metallic layer 72 on the upper surface side of insulating substrate 7. This allows the back electrode of power semiconductor element 1 and left-hand metallic layer 72 on the upper surface side of insulating substrate 7 to mechanically and electrically be connected. The material of joining material 6 is, for example, high-temperature solder containing lead (Pb) and tin (Sn). However, the material used for joining material 6 is not limited thereto. The material of joining material 6 may be, for example, an Ag nanoparticle paste or a Cu nanoparticle paste. Alternatively, the material of joining material 6 may be an electroconductive adhesive containing Ag particles or Cu particles and an epoxy resin or the like.

Insulating substrate 7 is a plate-shaped member. Insulating substrate 7 has an upper surface layer, an intermediate layer, and a lower surface layer. Insulating substrate 7 has, as an intermediate layer, insulating layer 71, has, as an upper surface layer, metallic layer 72 on the upper surface side of insulating layer 71, and has, as a lower surface layer, a metallic layer 73 on the lower surface side of insulating layer 71. Insulating substrate 7 has a plate shape. When plate-shaped insulating substrate 7 is viewed in plan view (from the upper surface side), the size of metallic layer 72 on the upper surface side of insulating layer 71 is smaller than that of insulating layer 71. The size of metallic layer 73 on the lower surface side of insulating layer 71 is smaller than that of insulating layer 71. The end of insulating layer 71 protrudes outward beyond the end of metallic layer 72 on the upper surface side of insulating layer 71 and the end of metallic layer 73 on the lower surface side of insulating layer 71. Such a configuration is intended to prevent creeping discharge (to keep a creepage distance) between metallic layer 72 on the upper surface side of insulating layer 71 and, for example a heat spreader joined to metallic layer 73 on the lower surface side of insulating layer 71 and insulating substrate 7 with insulating layer 71 being interposed between them.

Metallic layer 72 on the upper surface side of insulating layer 71 may be divided into two or more parts to form a circuit pattern depending on the purpose. In FIG. 1, power semiconductor element 1 and wires 5 are respectively disposed on metallic layers 72.

The material of metallic layer 72 on the upper surface side of insulating substrate 7 and metallic layer 73 on the lower surface side of insulating substrate 7 may be, for example, Al, Cu, Ni, Au, or an alloy mainly containing any of these from the viewpoint of electrical characteristics, thermal characteristics, and mechanical characteristics. However, the material used for metallic layer 72 on the upper surface side of insulating substrate 7 and metallic layer 73 on the lower surface side of insulating substrate 7 is not limited thereto. It should be noted that the upper surface side of insulating substrate 7 is synonymous with the upper surface side of insulating layer 71, and the lower surface side of insulating substrate 7 is synonymous with the lower surface side of insulating layer 71.

The material of insulating layer 71 of insulating substrate 7 may be, for example, a ceramic board made of aluminum oxide (Al₂O₃), aluminum nitride (AlN), or silicon nitride (Si₃N₄). However, the material of the ceramic board is not limited thereto. Alternatively, the material of insulating layer 71 of insulating substrate 7 may be an organic material filled with a ceramic filler. Such an organic material may be an epoxy resin, a polyimide resin, or a cyanate-based resin. The ceramic filler may be Al₂O₃, AlN, or boron nitride (BN).

The upper surface of insulating layer 71 is joined to metallic layer 72 (circuit pattern plate) by a method such as brazing or direct joining. The lower surface of insulating layer 71 is joined to metallic layer 73 (heat-dissipating plate) by a method such as brazing or direct joining.

Wires 5 as a wiring member are joined to the upper surface of metal foil 3 joined to the upper surface of surface electrode 2 of power semiconductor element 1 via stir region 4. Wires 5 are preferably formed of a material having excellent electrical conductivity, and such a material may be, for example, Cu, Al, or an alloy containing at least one of these. Wires 5 can directly be joined to the upper surface of metal foil 3 by ultrasonic welding. However, the material used for wires 5 and the joining method are not limited thereto.

Metal foil 3 is a plate (foil)-shaped metallic thin member. Metal foil 3 is directly joined to surface electrode 2 on the front surface of power semiconductor element 1 via stir region 4. The material of metal foil 3 may be Al, Cu, Ni, Au, Molybdenum (Mo), or an alloy mainly containing any of these from the viewpoint of electrical characteristics, thermal characteristics, and mechanical characteristics. However, the material used for metal foil 3 is not limited thereto.

Metal foil 3 can directly be joined onto surface electrode 2 on the front surface of power semiconductor element 1 by ultrasonic welding or laser welding without using a joining material. Such a region where metal foil 3 is directly joined to surface electrode 2 corresponds to stir region 4. These joining methods make it possible to form, at the interface between the lower surface of metal foil 3 and the upper surface of surface electrode 2, stir region 4 as a joint where the material of surface electrode 2 intrudes into metal foil 3 and the material of metal foil 3 intrudes into surface electrode 2 (the material of surface electrode 2 and the material of metal foil 3 are mutually dispersed). Stir region 4 is not formed throughout the interface between surface electrode 2 and metal foil 3 but is partially formed. When stir region 4 is partially formed by, for example, ultrasonic welding, a jig having a contact surface (protrusion) whose shape corresponds to the shape of stir region 4 is used so that pressure welding can be performed at a region where stir region 4 should be formed. In the case of laser welding, a region where stir region 4 should be formed is irradiated with a laser so that stir region 4 can have a desired shape.

The thickness of metal foil 3 is preferably in the range of 10 μm to 200 μm. When metal foil 3 is joined onto the upper surface of surface electrode 2, mechanical energy and thermal energy need to be imparted to form stir region 4. Therefore, if the thickness of metal foil 3 is thinner (less) than 10 μm, mechanical energy and thermal energy easily propagate also to power semiconductor element 1 so that power semiconductor element 1 may be damaged. On the other hand, if the thickness of metal foil 3 is thicker (greater) than 200 μm, excessive mechanical energy and thermal energy are required to form stir region 4 so that power semiconductor element 1 may be damaged. For this reason, the thickness of metal foil 3 is preferably greater than or equal to 10 μm and less than or equal to 200 μm in order to prevent damage to power semiconductor element 1 and form satisfactory stir region 4.

The outer peripheral region (outer periphery) of metal foil 3 is preferably in an unjoined state (in a state where it is not joined to surface electrode 2). Stress generated between metal foil 3 and surface electrode 2 is mainly generated at the outer periphery and corners of metal foil 3. Therefore, when the outer periphery of metal foil 3 and surface electrode 2 are in an unjoined state, it is possible to obtain the effect of reducing stress generated at the end of the metal foil. The size of outer periphery of metal foil 3 not joined to surface electrode 2 is preferably greater than or equal to 5 μm from the end (outer edge) of metal foil 3. When the start point of stir region 4 is separated inward from the outer edge of metal foil 3 by greater than or equal to 5 μm, stress generated in metal foil 3 can be reduced by deformation of unjoined region of metal foil 3 even when stress is generated at the end of metal foil. 3. However, the size of metal foil 3 and the joining method are not limited thereto. It should be noted that the state where metal foil 3 is not joined to the upper surface of surface electrode 2 refers to a state where an end 32 of metal foil 3 is movable without being peeled off from the upper surface of surface electrode 2 when stress is generated at end 32 of metal foil 3.

Conventionally, surface electrode 2 and metal foil 3 are joined using a joining material, but such a joining process requires heat treatment performed at a high temperature of about 200 to 300° C. Therefore, a joint between power semiconductor element 1 and insulating substrate 7 may be deteriorated by remelting or structural change of solder 6 at the joint due to thermal damage by the heat treatment. However, the present disclosure makes it possible to prevent thermal damage to semiconductor device 100, because metal foil 3 is directly joined to surface electrode 2 on the front surface of power semiconductor element 1 without interposing a metal sintered layer or the like between them to eliminate the need for heat treatment. Further, wires 5 as a wiring member are joined onto the upper surface of metal foil 3, which makes it possible to join a wiring member such as wires 5 without damage to power semiconductor element 1 during joining of wires 5.

It should be noted that the configuration of semiconductor device 100 is not limited to such a configuration as described above. For example, an insulating sheet may be used instead of insulating substrate 7 without providing, in semiconductor device 100, insulating layer 71 and metallic layer 73 on the lower surface side of insulating substrate 7 so that a circuit pattern is constituted from a metallic layer on the upper surface side of the insulating sheet. Further, although not shown in FIGS. 1 and 2, semiconductor device 100 may include a sealing member to guarantee insulating characteristics, a terminal to electrically connect semiconductor device 100 to the outside, and a housing for semiconductor device 100.

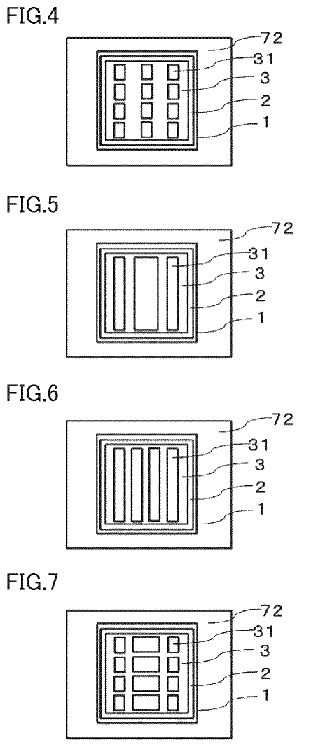

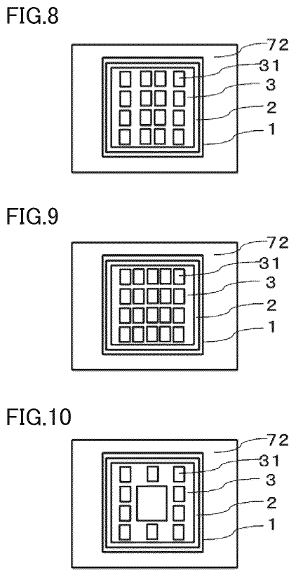

FIG. 3 is a schematic view showing the planar structure of a metal foil of the semiconductor device according to Embodiment 1. FIG. 4 is a schematic view showing the planar structure of a metal foil of another semiconductor device according to Embodiment 1. FIG. 5 is a schematic view showing the planar structure of a metal foil of another semiconductor device according to Embodiment 1. FIG. 6 is a schematic view showing the planar structure of a metal foil of another semiconductor device according to Embodiment 1. FIG. 7 is a schematic view showing the planar structure of a metal foil of another semiconductor device according to Embodiment 1. FIG. 8 is a schematic view showing the planar structure of a metal foil of another semiconductor device according to Embodiment 1. FIG. 9 is a schematic view showing the planar structure of a metal foil of another semiconductor device according to Embodiment 1. FIG. 10 is a schematic view showing the planar structure of a metal foil of another semiconductor device according to Embodiment 1. FIG. 3 to FIG. 10 show the shape and position of stir region 4 as a joint between metal foil 3 and surface electrode 2.

In FIG. 3 to FIG. 10, dent 31 of metal foil 3 is a joint where metal foil 3 is partially joined to the upper surface of surface electrode 2. Dent 31 of metal foil 3 is joined to part of the upper surface of surface electrode 2. In FIG. 3, metal foil 3 has a plurality of dents 31 arranged in a stripe pattern with predetermined intervals. In FIG. 4, metal foil 3 has a plurality of dents 31 divided and arranged like islands with predetermined intervals as in the case of FIG. 3. In FIG. 5, metal foil 3 has a plurality of dents 31 arranged so that dent 31 in the central region of power semiconductor element 1, through which electric current concentratively flows during operation of power semiconductor element 1, has a large area of contact with surface electrode 2. In FIG. 6, metal foil 3 has a plurality of dents 31 arranged in a stripe pattern so that the number of dents 31 is larger than that in FIG. 5 while the area of contact with surface electrode 2 in FIG. 5 is kept. In FIG. 7, metal foil 3 has a plurality of dents 31 arranged like islands as in the case of FIG. 4, but the contact area of each of island-like dents 31 in the central region is larger than that of each of island-like dents 31 disposed on the both sides of the central region. In FIG. 8, metal foil 3 has a plurality of dents 31 corresponding to ones obtained by dividing each of island-like dents 31 disposed in the central region in FIG. 7. In FIG. 9, metal foil 3 has a plurality of dents 31 corresponding to ones obtained by increasing the number of dents 31 in the central region in FIG. 8 to reduce the current density of the central region of metal foil 3. In FIG. 10, a metal foil 3 has a plurality of dents 31 arranged so that dent 31 having a large contact area is disposed in the central region so as to be surrounded by dents 31 having a small contact area. In FIG. 3 to FIG. 10, dents 31 are surrounded by the contact region between surface electrode 2 and metal foil 3.

Particularly, the size and total area of the joint region between metal foil 3 and surface electrode 2 are not limited, but may appropriately be set according to the allowable electric current (electric power) of power semiconductor element 1 to be used. These dents 31 can be formed by, for example, processing the contact surface of a jig for pressure welding of metal foil 3 to surface electrode 2.

Hereinbelow, the function and effect of the present embodiment will be described.

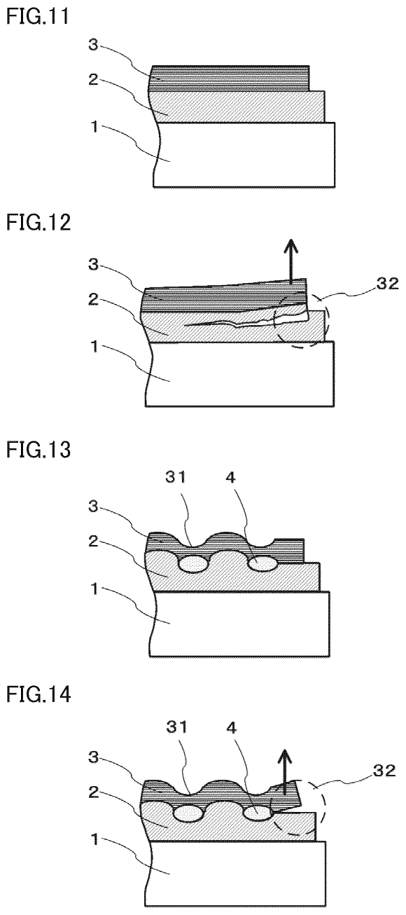

FIG. 11 is a schematic view showing the sectional structure of outer periphery of a conventional semiconductor device. FIG. 12 is a schematic view showing the sectional structure of outer periphery of the conventional semiconductor device. FIG. 13 is a schematic view showing the sectional structure of outer periphery of the semiconductor device according to Embodiment 1. FIG. 14 is a schematic view showing the sectional structure of outer periphery of the semiconductor device according to Embodiment 1. FIG. 11 and FIG. 12 relate to a conventional joint structure. FIG. 13 and FIG. 14 show a joint structure using metal foil 3.

As shown in FIG. 11 and FIG. 12, in the case of a conventional joint structure, surface electrode 2 and metal foil 3 are joined in such a manner that metal foil 3 is entirely joined to the upper surface of surface electrode 2. Therefore, when stress is generated at end 32 of metal foil 3, for example, when stress is upwardly generated in metal foil 3 as shown by an arrow in FIG. 12, end 32 of metal foil 3 is pulled upwardly by the stress. As a result, surface electrode 2 is pulled by metal foil 3 so that force is exerted on a portion weaker than the joint between surface electrode 2 and metal foil 3, and a crack is generated in surface electrode 2. The generated crack develops toward the central region of power semiconductor element 1. The development of the crack causes electric current flowing through power semiconductor element 1 as a current pathway to concentrate on a portion that has not been peeled off by the crack so that heat generation or the like occurs, which causes the deterioration of reliability of the semiconductor device. Then, such a crack further develops, the area of contact between surface electrode 2 and metal foil 3 reduces, which causes an increase in thermal resistance or electric resistance and finally leads to the failure of the semiconductor device.

However, as shown in FIG. 13 and FIG. 14, in the case of a structure using metal foil 3, surface electrode 2 and metal foil 3 are partially joined via surface electrode 2 and stir region 4. Particularly, surface electrode 2 and metal foil 3 are not joined in the outer periphery of metal foil 3. Therefore, when stress is generated at end 32 of metal foil 3, for example, when stress is upwardly generated in metal foil 3 as shown by an arrow in FIG. 14, end 32 of metal foil 3 is pulled upwardly by the stress. However, when a region sufficient for stress reduction (prevention of stress transfer) is kept by the distance of the unjoined region between the upper surface of surface electrode 2 and metal foil 3 in the outer periphery of metal foil 3, only the unjoined region in the outer periphery of metal foil 3 is pulled by the stress generated at end 32 of metal foil 3. Therefore, the stress does not influence a region inside the unjoined region between metal foil 3 and the upper surface of surface electrode 2 (central region of power semiconductor element 1) so that peeling-off does not occur at stir region 4. Therefore, unlike the case shown in FIG. 12 where metal foil 3 is entirely joined to the surface electrode, development of a crack does not occur. As a result, electric current flowing through power semiconductor element 1 does not locally concentrate, which makes it possible to prevent the deterioration of reliability of the semiconductor device.

As described above, since metal foil 3 is joined to the upper surface of surface electrode 2 via stir region 4, stress generated at end 32 of metal foil 3 can be reduced, which makes it possible to prevent peeling-off of metal foil 3 from the upper surface of surface electrode 2. As a result, the reliability of the semiconductor device can be enhanced. Further, the life of the semiconductor device can be increased.

Further, since metal foil 3 is directly joined to surface electrode 2 on the front surface of power semiconductor element 1 by ultrasonic welding or laser welding without interposing a metal sintered material between them, it is not necessary to perform heat treatment on the entire semiconductor device, which makes it possible to prevent thermal damage to a constituent inside the semiconductor device, such as solder 6.

Further, since metal foil 3 is joined onto the upper surface of surface electrode 2, power semiconductor element 1 is not damaged even when wires 5 as a high-strength material, such as Cu wires, are joined to the upper surface of metal foil 3, which makes it possible to obtain a semiconductor device having high reliability.

Hereinbelow, a method for producing semiconductor device 100 according to the present embodiment will be described.

The main production process of Embodiment 1 is roughly divided into the following three steps: a first step in which power semiconductor element 1 or the like is joined onto insulating substrate 7 (power semiconductor element mounting step); a second step in which metal foil 3 is joined onto the surface electrode of power semiconductor element 1 (metal foil joining step); and a third step in which circuit wiring is performed using wires 5 on insulating substrate 7 (wiring forming step). Semiconductor device 100 can be produced through these steps.

First, power semiconductor element 1 is joined (disposed) in a predetermined position on left-hand metallic layer 72 on the upper surface side of insulating substrate 7 (power semiconductor element mounting step). Power semiconductor element 1 is joined using solder 6 as a joining material.

Then, metal foil 3 is joined onto the upper surface of surface electrode 2 of power semiconductor element 1 disposed on the upper surface of metallic layer 72 on the upper surface of insulating substrate 7 (metal foil joining step). Surface electrode 2 on the front surface of power semiconductor element 1 and metal foil 3 are joined by, for example, ultrasonic welding. When the tip (contact surface with metal foil 3) of a jig for ultrasonic welding has a shape corresponding to the shape of stir region 4 that should be formed, stir region 4 where metal foil 3 is partially joined to surface electrode 2 can be formed to have a desired shape in a desired position.

Then, metallic layer 72 to which power semiconductor element 1 has been joined and another metallic layer 72 constituting a circuit pattern are connected using wires 5 (wiring forming step). The position where the upper surface of metal foil 3 joined to the front surface of power semiconductor element 1 and wires 5 are joined can be selected according to electric current (electric power) handled by power semiconductor element 1, and is desirably located in a region having a high current density and a large joint area.

Semiconductor device 100 can be produced through these steps.

Further, for example, insulating substrate 7 is joined (disposed) to the upper surface of a heat spreader according to the form of the power module. In the outer peripheral region of the upper surface of the heat spreader, a frame body is disposed to surround insulating substrate 7 (step of mounting onto heat spreader). Insulating substrate 7 is usually joined using solder. The frame body is usually bonded (joined) using an adhesive.

Then, the region in which insulating substrate 7 is disposed and which is surrounded by the frame body and the heat spreader is filled with a sealing member (sealing member filling step). After the filling with the sealing member, a lid is disposed on the upper surface of the frame body filled with the sealing member to seal insulating substrate 7 in the frame body (insulating substrate sealing step).

Then, if necessary, the lower surface of the heat spreader and the upper surface of a cooling unit are connected. The heat spreader and the cooling unit are connected using a bolt (cooling unit disposing step).

Semiconductor device 100 including the cooling unit can be produced through these steps.

In the semiconductor device having such a configuration as described above, since metal foil 3 is provided on the upper surface of surface electrode 2 with stir region 4 being interposed between them, stress generated at end 32 of metal foil 3 can be reduced, which makes it possible to prevent peeling-off of metal foil 3 from the upper surface of surface electrode 2. As a result, the reliability of the semiconductor device can be enhanced. Further, the life of the semiconductor device can be increased.

Further, since metal foil 3 is directly joined to surface electrode 2 on the front surface of power semiconductor element 1 by ultrasonic welding or laser welding without interposing a metal sintered material between them, it is not necessary to perform heat treatment on the entire semiconductor device, which makes it possible to prevent thermal damage to a constituent inside the semiconductor device, such as solder 6.

Further, since metal foil 3 is joined onto the upper surface of the surface electrode, power semiconductor element 1 is not damaged even when wires 5 as a high-strength material, such as Cu wires, are joined to the upper surface of metal foil 3, which makes it possible to obtain a semiconductor device having high reliability.

### Embodiment 2

Embodiment 2 is different in that wires 5 used as a wiring member in Embodiment 1 are replaced with a plate-shaped wiring member 8. Also in such a case where plate-shaped wiring member 8 is used as a wiring member, metal foil 3 is partially joined to surface electrode 2 on the front surface of power semiconductor element 1 via stir region 4, which makes it possible to reduce stress at end 32 of metal foil 3, and prevent generation of a crack in surface electrode 2. It should be noted that other points are the same as those of Embodiment 1, and therefore detailed description thereof will not be repeated.

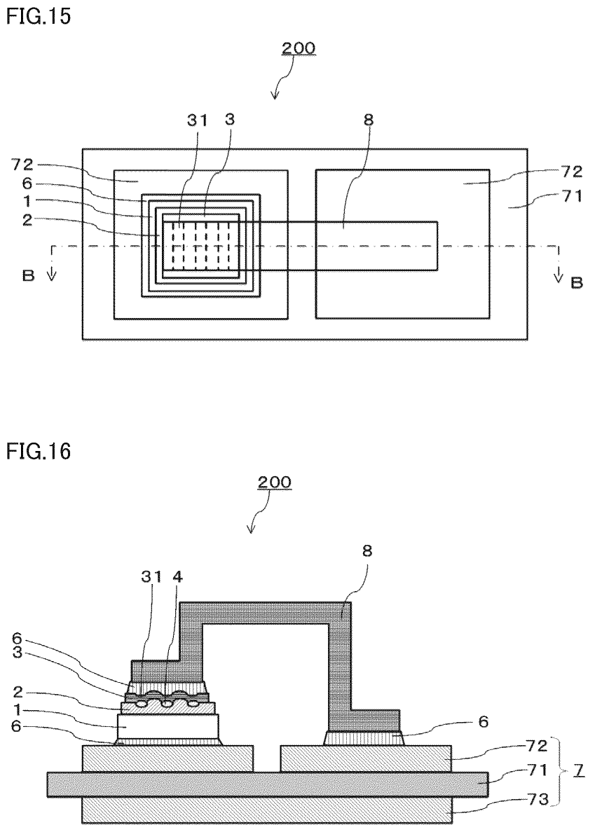

FIG. 15 is a schematic view showing the planar structure of a semiconductor device according to Embodiment 2. FIG. 16 is a schematic view showing the sectional structure of the semiconductor device according to Embodiment 2. FIG. 16 is a schematic sectional structural view taken along a dashed-dotted line BB shown in FIG. 15.

In the drawings, a semiconductor device 200 includes a power semiconductor element 1 as a semiconductor element, a surface electrode 2, a metal foil 3, a stir region 4, a plate-shaped wiring member 8 as a wiring member, solder 6 as a joining material, and an insulating substrate 7.

In the drawings, the back surface of power semiconductor element 1 is joined to a metallic layer 72 on the upper surface side of insulating substrate 7 with solder 6. On the front surface of power semiconductor element 1, surface electrode 2 is formed. On the upper surface of surface electrode 2, metal foil 3 is formed. Surface electrode 2 and metal foil 3 are partially joined, and a joint region corresponds to stir region 4. On the upper surface of metal foil 3, plate-shaped wiring member 8 as a wiring member is formed. It should be noted that a dent 31 of metal foil 3 is indicated by dotted lines.

In the drawings, semiconductor device 100 is configured to have one power module having one power semiconductor element 1 and three wires 5. However, semiconductor device 100 may be configured to have a plurality of power modules each having one or more power semiconductor elements 1 and wires 5, the number of which is less than three or greater than or equal to three.

FIG. 15 is a schematic planar structural view when semiconductor device 200 is viewed from the upper surface side. In FIG. 15, the outermost full line corresponds to the outer edge of an insulating layer 71 of insulating substrate 7. On the inner side of the outer edge of insulating layer 71 of insulating substrate 7, metallic layer 72 on the upper surface side of insulating substrate 7 is disposed. In FIG. 15, two metallic layers 72 are disposed on the upper surface of insulating layer 71 of insulating substrate 7. On the inner side of the outer edge of left-hand metallic layer 72 on the upper surface side of insulating substrate 7, power semiconductor element 1 is disposed. On the inner side of the outer edge of front surface of power semiconductor element 1, surface electrode 2 is disposed. On the inner side of the outer edge of surface electrode 2, metal foil 3 is disposed. On the upper surface of metal foil 3, dent 31 (dotted lines) of metal foil 3 is disposed in a region corresponding to stir region 4 as a joint region between surface electrode 2 and the lower surface of metal foil 3. On the upper surface of metal foil 3, plate-shaped wiring member 8 is disposed. Plate-shaped wiring member 8 is disposed across a gap (space) between the opposed outer edges of right-hand metallic layer 72 and left-hand metallic layer 72 on the upper surface side of insulating substrate 7. Plate-shaped wiring member 8 is disposed on power semiconductor element 1 on the inner side of the outer edge of left-hand metallic layer 72 on the upper surface side of insulating substrate 7 and on the inner side of the outer edge of right-hand metallic layer 72.

FIG. 16 is a schematic sectional view of semiconductor device 200. In FIG. 16, the back surface of power semiconductor element 1 is joined to left-hand metallic layer 72 on the upper surface side of insulating substrate 7 with solder 6. On the upper surface of surface electrode 2 on the front surface of power semiconductor element 1, metal foil 3 is disposed. The lower surface of metal foil 3 and the front surface of surface electrode 2 are partially joined via stir region 4. Metal foil 3 has an unlevel (wavy) sectional shape. Metal foil 3 is joined to the upper surface of surface electrode 2 of power semiconductor element 1 by pressing metal foil 3 against the upper surface of surface electrode 2 with a jig. At this time, dent 31 is formed in metal foil 3 as an indentation. A region between adjacent dents 31 is in contact with surface electrode 2 deformed and lifted in reflection of the shape of metal foil 3. In the outer peripheral region of metal foil 3, the lower surface of metal foil 3 is not joined to the upper surface of surface electrode 2 of power semiconductor element 1. Therefore, the outer peripheral region of metal foil 3 can change in shape. One end of plate-shaped wiring member 8 is connected (joined) to the upper surface of metal foil 3 with solder 6 as a joining material. The other end of plate-shaped wiring member 8 is joined to the upper surface of right-hand metallic layer 72 of insulating substrate 7 with solder 6.

Plate-shaped wiring member 8 is joined to metal foil 3 and right-hand metallic layer 72 of insulating substrate 7 with solder 6 as a joining material. Plate-shaped wiring member 8 is preferably formed of a material having excellent electrical conductivity, and such a material may be, for example, Cu, Al, or an alloy containing at least one of these. However, the material used for plate-shaped wiring member 8 is not limited thereto.

As described above, since metal foil 3 is provided on the upper surface of surface electrode 2 with stir region 4 being interposed between them, stress generated at end 32 of metal foil 3 can be reduced, which makes it possible to prevent peeling-off of metal foil 3 from the upper surface of surface electrode 2. As a result, the reliability of the semiconductor device can be enhanced. Further, the life of the semiconductor device can be increased.

Further, since plate-shaped wiring member 8 is joined to metal foil 3 and metallic layer 72 on the upper surface side of insulating substrate 7 with solder 6, a higher current density can be achieved.

Further, a plurality of semiconductor devices 200 can collectively be subjected to joining with solder 6 during processing of semiconductor devices 200 in the step of joining with solder 6, which simplifies the production process as compared to a case where plate-shaped wiring members 8 are joined one by one.

In the semiconductor device having such a configuration as described above, since metal foil 3 is provided on the upper surface of surface electrode 2 with stir region 4 being interposed between them, stress generated at end 32 of metal foil 3 can be reduced, which makes it possible to prevent peeling-off of metal foil 3 from the upper surface of surface electrode 2. As a result, the reliability of the semiconductor device can be enhanced. Further, the life of the semiconductor device can be increased.

Further, since plate-shaped wiring member 8 is joined to metal foil 3 and metallic layer 72 on the upper surface side of insulating substrate 7 with solder 6, a higher current density can be achieved.

Further, a plurality of semiconductor devices 200 can collectively be subjected to joining with solder 6 during processing of semiconductor devices 200 in the step of joining with solder 6, which simplifies the production process as compared to a case where plate-shaped wiring members 8 are joined one by one.

### Embodiment 3

Hereinbelow, a power converting device to which the semiconductor device described above with reference to Embodiments 1 and 2 is applied will be described. The present disclosure is not limited to a specific power converting device, but Embodiment 3 will be described below with reference to a case where the present disclosure is applied to a three-phase inverter.

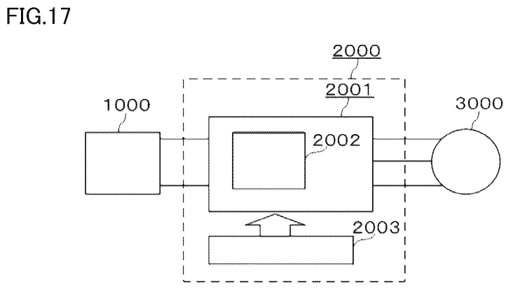

FIG. 17 is a block diagram showing the configuration of a power converting system to which the power converting device according to the present embodiment is applied. The power converting system shown in FIG. 17 is constituted from a power source 1000, a power converting device 2000, and a load 3000. Power source 1000 is a direct-current power source, and supplies direct-current power to power converting device 2000. Power source 1000 can be constituted from any of various components such as a direct-current system, a solar cell, and a secondary battery. Alternatively, the power source 1000 may be constituted from a rectifier circuit or an AC/DC converter connected to an alternating-current system. Alternatively, power source 1000 may be constituted from a DC/DC converter to convert direct-current power that is output from a direct-current system into predetermined electric power.

Power converting device 2000 is a three-phase inverter connected between power source 1000 and load 3000, and converts direct-current power supplied from power source 1000 into alternating-current power to supply alternating-current power to load 3000. As shown in FIG. 17, power converting device 2000 includes a main converting circuit 2001 to convert direct-current power into alternating-current power and output the alternating-current power and a control circuit 2003 to output a control signal for controlling main converting circuit 2001 to main converting circuit 2001.

Load 3000 is a three-phase electric motor driven by alternating-current power supplied from power converting device 2000. It should be noted that load 3000 is not limited to one for specific use, and is an electric motor installed in any of various electric machines such as hybrid automobiles, electric cars, railway vehicles, elevators, and air conditioners.

Hereinbelow, the details of power converting device 2000 will be described. Main converting circuit 2001 includes a switching element and a free wheel diode (not shown). When the switching element is switched, direct-current power supplied from power source 1000 is converted into alternating-current power, and the alternating-current power is supplied to load 3000. A specific circuit configuration of main converting circuit 2001 may be any of various circuit configurations, but main converting circuit 2001 according to the present embodiment is a two-level three-phase full-bridge circuit that can be constituted from six switching elements and six free wheel diodes respectively connected in inverse parallel to the switching elements.

At least any of the switching elements and the free wheel diodes of main converting circuit 2001 is a switching element or a free wheel diode that a semiconductor device 2002 corresponding to the semiconductor device according to at least any of Embodiments 1 to 5 described above has. The six switching elements are connected in series two by two to constitute upper and lower arms, and the sets of the upper and lower arms respectively constitute the phases (U phase, V phase, W phase) of the full-bride circuit. The output terminals of the sets of the upper and lower arms, that is, three output terminals of main converting circuit 2001 are connected to load 3000.

Main converting circuit 2001 includes a driving circuit (not shown) to drive the switching elements. The driving circuit may be included in semiconductor device 2002 or may be provided separately from semiconductor device 2002. The driving circuit generates driving signals for driving the switching elements of main converting circuit 2001 and supplies the driving signals to the control electrodes of the switching elements of main converting circuit 2001. Specifically, the driving circuit outputs a driving signal for turning on the switching element and a driving signal for turning off the switching element to the control electrodes of the switching elements according to a control signal from control circuit 2003 that will be described later. When the switching element is maintained turned-on, the driving signal is a voltage signal (ON signal) greater than or equal to the threshold voltage of the switching element, and when the switching element is maintained turned-off, the driving signal is a voltage signal (OFF signal) less than or equal to the threshold voltage of the switching element.

Control circuit 2003 controls the switching elements of main converting circuit 2001 so that desired electric power is supplied to load 3000. Specifically, the time (ON time) when each of the switching elements of main converting circuit 2001 is turned on is calculated on the basis of electric power that should be supplied to load 3000. For example, main converting circuit 2001 can be controlled by PWM control such that the ON times of the switching elements are modulated according to a voltage that should be output. Then, control circuit 2003 outputs a control command (control signal) to the driving circuit included in main converting circuit 2001 so that an ON signal and an OFF signal are respectively output to the switching element that should be turned on and the switching element that should be turned off at each time point. The driving circuit outputs, as a driving signal, an ON signal or an OFF signal to the control electrode of each of the switching elements according to this control signal.

Power converting device 2000 according to the present embodiment uses the semiconductor device according to any of Embodiments 1 to 5 as semiconductor device 2002 constituting main converting circuit 2001. This makes it possible to prevent a longitudinal crack of solder 6 for joining power semiconductor element 1 to insulating substrate 7. This, as a result, makes it possible to enhance the reliability of power converting device 2000.

The present embodiment has been described with reference to a case where the present disclosure is applied to a two-level three-phase inverter, but the present disclosure can be applied not only to that but also to various power converting devices. The power converting device according to the present embodiment is a two-level power converting device, but the present disclosure may be applied to a three-level or multi-level power converting device. When electric power is supplied to a single-phase load, the present disclosure may be applied to a single-phase inverter. Further, when electric power is supplied to a direct-current load or the like, the present disclosure can be applied to a DC/DC converter or an AC/DC converter.

The power converting device to which the present disclosure is applied is not limited to one used when the load is an electric motor, and can be used also as, for example, a power source device of an electric discharge machine, a laser beam machine, an induction heating-type cooking apparatus, or a wireless charging system, and further can be used as a power conditioner for a solar power generation system, a power storage system, or the like.

It should be noted that if necessary, the semiconductor devices described with reference to the embodiments can freely be combined.

The embodiments disclosed herein are only illustrative, and the present disclosure is not limited thereto. The scope of the present disclosure is defined by claims rather than the above description, and is intended to include all modifications within the spirit and scope equivalent to the claims.

### REFERENCE SIGNS LIST

1: power semiconductor element, 2: surface electrode, 3: metal foil, 4: stir region, 5: wire, 6: solder, 7: insulating substrate, 8: plate-shaped wiring member, 31: dent, 32: end of metal foil 3, 71: insulating layer, 72, 73: metallic layer, 100, 101, 200, 2002: semiconductor device, 1000: power source, 2000: power converting device, 2001: main converting circuit, 2003: control circuit, 3000: load

1. A semiconductor device comprising:
a semiconductor element having a front surface and a back surface;
a surface electrode formed on the front surface of the semiconductor element; and
a metal foil having an upper surface and a lower surface that are wavy in sectional shape, having a depressed portion that is a dent as seen from the upper surface, and being partially joined, at the dent, onto an upper surface of the surface electrode, wherein
a region of the surface electrode located between the dents adjacent to each other is lifted and in contact with the lower surface of the metal foil, and
an outer peripheral region of the metal foil is not joined to the upper surface of the surface electrode.

2. (canceled)

3. The semiconductor device according to claim 1, wherein the surface electrode and the metal foil are directly joined.

4. The semiconductor device according to claim 3, wherein in a region where the surface electrode and the metal foil are directly joined, a stir region is formed.

5. The semiconductor device according to claim 1, wherein a material of the metal foil is aluminum, copper, nickel, gold, molybdenum, or an alloy mainly containing any of these.

6. The semiconductor device according to claim 1, wherein a wiring member is disposed on the upper surface of the metal foil.

7. The semiconductor device according to claim 6, wherein the wiring member is directly joined to the metal foil.

8. The semiconductor device according to claim 6, wherein the wiring member is joined to the upper surface of the metal foil via a joining material.

9. The semiconductor device according to claim 6, wherein a material of the wiring member is copper, aluminum, or an alloy containing at least one of these.

10. A power converting device comprising:
a main converting circuit including the semiconductor device according to claim 1, to convert input electric power and output the converted electric power; and
a control circuit to output a control signal for controlling the main converting circuit to the main converting circuit.
